(19) United States
(12) Patent Application Publication
(10) Pub. No.: US 2021/0293495 A1
(43) Pub. Date: Sep. 23, 2021

(54) MECHANISM FOR VARIABLE THERMAL CONDUCTANCE

(71) Applicant: NORTHROP GRUMMAN SYSTEMS CORPORATION, Falls Church, VA (US)

(72) Inventors: MICHAEL T. BARAKO, REDONDO BEACH, CA (US); DARREN V. LEVINE, LOS ANGELES, CA (US); IAN M. KUNZE, LOS ANGELES, CA (US); JESSE B. TICE, TORRANCE, CA (US)

(21) Appl. No.: 16/821,502

(22) Filed: Mar. 17, 2020

(51) Int. Cl. F28F 13/00; F28C 3/00; F28F 21/02; F28F 21/06

(52) U.S. Cl. CPC F28F 13/00; F28C 3/005; F28F 2013/006; F28F 21/06; F28F 21/02

(57) ABSTRACT

A thermal management system for transferring heat to and from a heat source. The system includes a thermal conductor thermally coupled to the heat source, a pressure dependent thermal conductance element thermally coupled to the conductor, and a heat sink thermally coupled to or thermally separable from the thermal conductance element. An actuator is configured relative to the thermal conductor, the thermal conductance element and the heat sink that controls the compression of the thermal conductance element between the thermal conductor and the heat sink so as to control the transfer of heat therebetween. The thermal conductance element can be compressible TIM element, such as a nanowire array, carbon nanotube forest, polymeric gasket, etc.

### BACKGROUND

### Field

This disclosure relates generally to a thermal management system that is capable of controlling the amount of heat transfer between a heat source and a heat sink and, more particularly, to a thermal management system that includes a pressure dependent thermal conductance element that is selectively compressed to control the transfer of heat between a heat source and a heat sink.

### Discussion

Most thermal systems that transfer heat from a heat source to a heat sink for thermal management of, for example, microelectronics are passive or static systems in that they have no control or minimal control over the rate of heat flow. These systems are generally symmetric and linear, where the rate of heat flow is proportional to the temperature difference. Also, these systems are typically designed for the extreme ends of the possible heat transfer. Further, heat can often flow in both directions in these systems, which makes it difficult to maintain the temperature of systems that want to retain heat when they aren't operating. These thermal management systems include systems that are highly sensitive to temperature, such as sensors, and systems that experience enormous thermal transients. For example, for electronics that are on a satellite that may be going into and out of the sun, it may be desirable to provide heat transfer from the electronics to the heat sink when the satellite is being exposed to the sun and retain heat when the satellite is not being exposed to the sun.

Currently, there is no way to build a thermal feedback control system having passive elements that can change in response to a stimulus. More specifically, there is currently no way to change the conductance of a passive thermal system, either through passive feedback or through active control. Further, for symmetric systems, heat can flow in either direction, but there is no available mechanism for heat flow control. Also, passive conductive elements can have a linear relationship between the temperature difference and the amount of heat that they transfer, but that rate cannot be adjusted.

Known nonlinear thermal elements, such as heat pipes, have a nonlinear relationship between heat transfer and temperature due to the phase change in the working fluid. However, many of these systems cannot be adjusted in real-time and must be hermetically sealed. Further, these nonlinear systems are not really conductive elements as they transport heat through working fluids rather than through solid-state conduction. Most active thermal solutions are fluid based, where mass flow control can be used to adjust the rate of heat transfer, but these systems are convection based heat exchangers rather than a conduction thermal control element.

It is be desirable to provide a thermal management system for some applications that is able to control the flow of heat from the heat source to the heat sink, such as turn on or off the flow of heat, increase or decrease the flow of heat, direct the flow of heat from one heat sink to another, etc.

### BRIEF DESCRIPTION OF THE DRAWINGS

FIG. 1 is a schematic diagram of a thermal management system including a circuit that is an electrical representation of a pressure dependent thermal conductance element with selectable output terminals;

FIG. 2 is an illustration of a thermal management system including a TIM element that is in full compression;

FIG. 3 is an illustration of the thermal management system shown in FIG. 2 where the TIM element in partial compression such that the interface is engaged;

FIG. 4 is an illustration of the thermal management system shown in FIG. 2 where the TIM element in under no compression and the interface is disengaged;

FIG. 5 is a side view of a thermal management system including a pressure dependent thermal conductance element and multiple outputs;

FIG. 6 is a side view of a thermal management system including tiled pressure dependent thermal conductance elements;

FIG. 7 is an illustration of a thermal management system including a pressure dependent thermal conductance element and multiple selectable output terminals;

FIG. 8 is an exploded isometric view of a rotary actuator that can be used in the thermal management system shown in FIG. 2;

FIG. 9 is a cross-sectional view of the rotary actuator shown in FIG. 8; and

FIG. 10 is an exploded, cut-away, isometric view of a thermal management system demonstrating active control and variable conductance.

### DETAILED DESCRIPTION OF THE EMBODIMENTS

The following discussion of the embodiments of the disclosure directed to a thermal management system including a pressure dependent thermal conductance element that is selectively compressed to control the heat transfer between a heat source and a heat sink is merely exemplary in nature, and is in no way intended to limit the disclosure or its applications or uses.

The present invention proposes a heat transfer device or thermal management system that employs a pressure dependent thermal conductance element that will prevent heat from being transferred from a heat source to a heat sink, allow a maximum amount of heat to be transferred from the heat source to the heat sink and control the amount of heat being transferred from the heat source to the heat sink between no heat transfer and the maximum heat transfer. More specifically, if the heat source is on one side of the pressure dependent thermal conductance element and the heat sink is on the other side of the element, if one of the heat source or heat sink is disengaged from the element, then no heat is transferred therebetween and if a maximum amount of compression pressure is applied to the heat source and the heat sink against the element, then the maximum amount of heat is transferred therebetween, where the pressure can be controlled to control the amount of heat transfer. Additionally, the heat transfer device can be configured to allow the heat to be selectively transferred from the heat source to any one of a plurality of heat sinks. Further, the thermal conductance element will scale linearly with applied pressure over a typical range of 0.1-10 MPa.

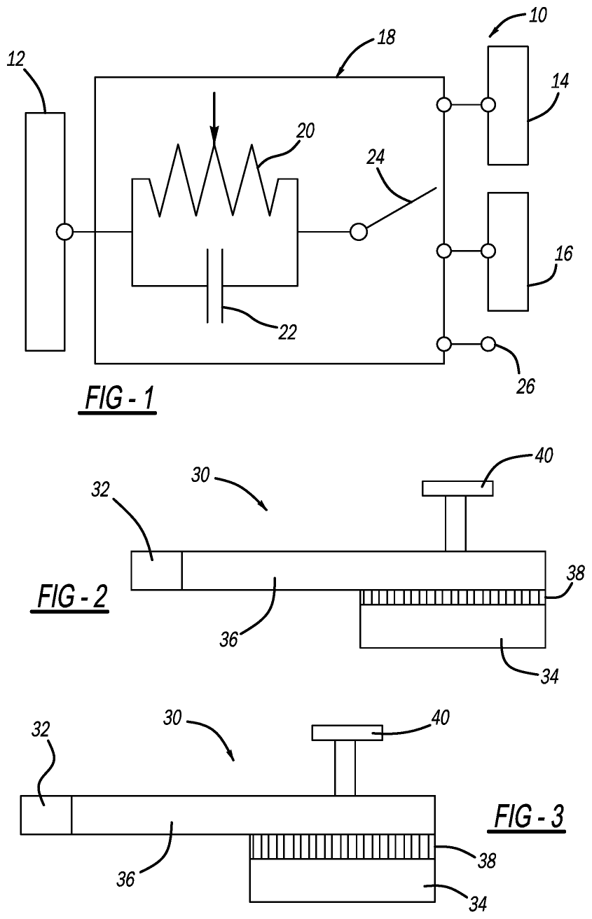

FIG. 1 is a schematic diagram of a thermal management system 10 including a heat source 12 and two heat sinks 14 and 16. The system 10 also includes a circuit 18 that is an electrical representation of the pressure dependent thermal conductance element referred to above. The circuit 18 includes a variable resistor 20 and a capacitor 22 electrical coupled in parallel and electrically coupled in series with a selector switch 24. The resistance of the resistor 20 can be set to represent the pressure on the thermal conductance element and the selector switch 24 can be set to direct the electrical signal, i.e., the heat, to one of the heat sinks 14 or 16, or to an open terminal 26 where there is no heat transfer.

In one non-limiting embodiment, the thermal conductance element is a compliant thermal interface material (TIM), such as a metal nanowire array, which is a forest of vertically aligned metal nanowires, such as copper, silver, gold, etc., typically having a density greater than 10⁷ cm⁻². Metal nanowire arrays are known to be used as a mechanism for an efficient and reliable transfer of heat from a source to a heat sink for thermal management of microelectronics. Metal nanowire arrays provide a soft and thermally conductive structure that is able to conform to and fill in gaps, for example, between a silicon die and a copper heat sink. More specifically, metal nanowire arrays are soft and deformable, which allows them to conform to rough surfaces and provide heat transfer capabilities. Furthermore, metal nanowire arrays are soft and compliant and can mitigate thermomechanical stresses at material interfaces, for example, stresses induced at the interface due to coefficient of thermal expansion mismatch. In other words, dense arrays of vertically aligned metal nanowires offer the unique combination of thermal conductance from a constituent metal and mechanical compliance from high aspect ratio geometry to increase interfacial heat transfer and device reliability. Metal nanowire arrays that are employed for thermal heat transfer purposes are typically fabricated by providing a porous membrane, used as a sacrificial template, such as a ceramic template, filling the pores in the template with metal using an electrodeposition process and then etching away the template. Thus, the length, diameter and density of the nanowires are determined by the geometry of the template, where the available configuration of the template sets the possible configuration of the nanowire array.

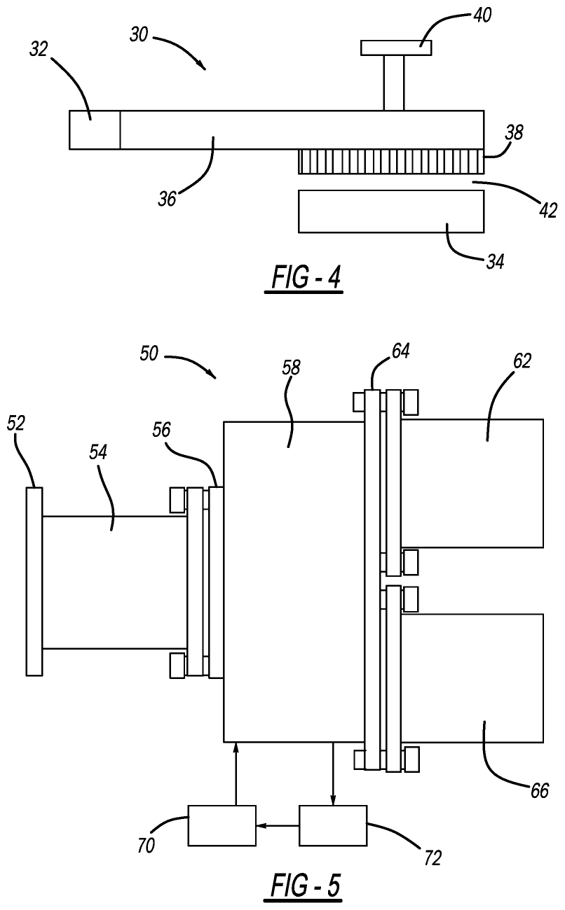

FIG. 2 is a depiction of a thermal management system 30 that is a general representation of the thermal management system discussed above, and includes a heat source 32, a heat sink 34 and a thermal conductor 36, such as a heat strap, heat pipe, heat spreader, etc. A compressible TIM element 38, such as a nanowire array, carbon nanotube forest, polymeric gasket, etc., is positioned between the conductor 36 and the heat sink 34, and an actuation mechanism 40 of any suitable type, some of which are discussed below, compresses the element 38 between the conductor 36 and the heat sink 34 to control the flow of heat. FIG. 2 shows the TIM element 38 in its fully compressed state where the maximum amount of heat is transferred from the conductor 36 to the heat sink 34. FIG. 3 shows the TIM element 38 in a controlled compressed state between maximum pressure and no pressure, where the desired amount of heat is transferred from the conductor 36 to the heat sink 34. FIG. 4 shows the TIM element 38 under no compression, i.e., no pressure, where a gap 42 is provided between the TIM element 38 and the heat sink 34 so that no heat is transferred from the conductor 36 to the heat sink 34. For this embodiment, the element 38 needs to be non-adhesive so that it can easily disengage the heat sink 34 over multiple cycles.

FIG. 5 is a side view of a thermal management system 50 showing that the heat transfer can be routed from a heat source to multiple heat sinks. The system 50 includes a heat source 52 coupled to a thermal strap 54, or other thermal conductor, that is bolted to one side of a thermally conductive plate 56, where a pressure dependent thermal conductance element 58 is pressed against an opposite side of the plate 56. A radiator 62 and a thermal storage device 66 are bolted to a thermally conductive plate 64 that is pressed against an opposite side of the element 58. An actuator 70 is actuated to control the compression between the plates 56 and 64 to control the heat transfer from the heat source 52 to the radiator 62 and the thermal storage device 66 as discussed herein. A sensor 72 senses the amount of heat being transferred through the element 58 and provides a heat measurement signal to the actuator 70 and the actuator 70 adjusts the compression between the plates 56 and 64 as desired in a feedback control loop.

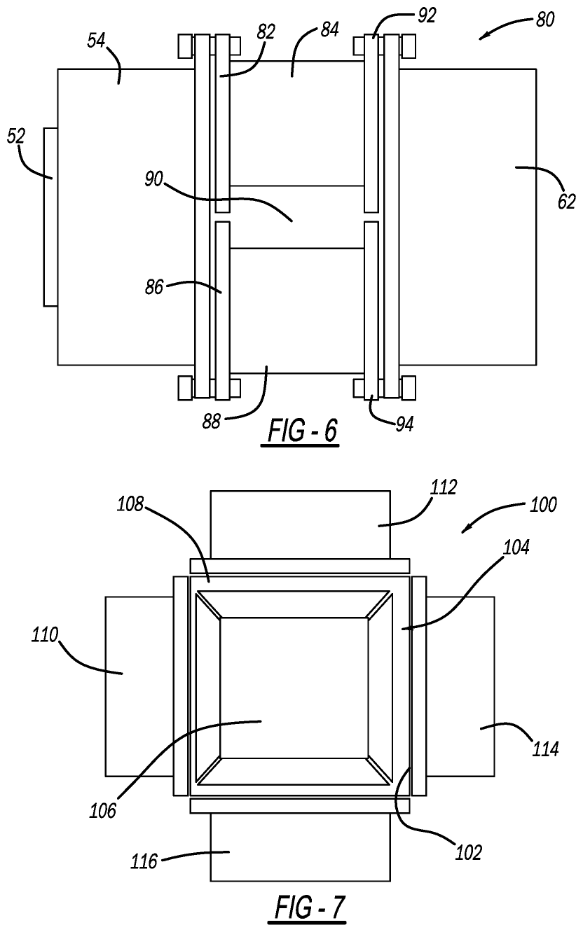

In other embodiments, multiple pressure dependent thermal conductance elements can be tiled in parallel, where the total conductance scales linearly with the number of elements to enable standardization of device size while still being useful for different applications. FIG. 6 is a side view of a thermal management system 80 illustrating this embodiment, where like elements to the system 50 are identified by the same reference number. The conductor 54 is bolted to one side of a thermally conductive plate 82, where a pressure dependent thermal conductance element 84 is pressed against an opposite side of the plate 82. The conductor 54 is also bolted to one side of a thermally conductive plate 86, where a pressure dependent thermal conductance element 88 is pressed against an opposite side of the plate 86, and where a gap 90 is provided between the elements 84 and 88. A thermally conductive plate 92 is pressed against an opposite side of the element 84, a thermally conductive plate 94 is pressed against an opposite side of the element 88, and the radiator 62 is bolted to the plates 92 and 94.

As mentioned above, the heat can be selectively transferred through the pressure dependent thermal conductance element to any one of a plurality of heat sinks. FIG. 7 illustrates this embodiment and shows a thermal management system 100 including a square structure 102 defining a vacuum chamber 104. A square pressure dependent thermal conductance element 106 is positioned within the chamber 104 and is connected to a single input terminal (not shown), where a gap 108 is defined between the structure 102 and the element 106. Four output terminals 110, 112, 114 and 116 are positioned against the four walls of the structure 102 outside of the chamber 104, where each terminal 110-116 would be thermally coupled to a separate heat sink or other thermal device (not shown). A separate actuator (not shown) would be provided for each of the terminals 110-116, where one of the actuators is actuated to move the element 106 in the chamber 104 to close the gap 108 between one of the terminals 110-116 and the element 106 to direct heat from the input terminal to that output terminal 110-116, where the element 106 is shown being coupled to the terminal 110.

The actuation mechanism 40 can be any actuation mechanism suitable for the purposes described herein. Specific examples include electric actuation, such as a linear drive motor, pneumatic actuation, such as a pneumatic drive, and expansion actuation, such as a thermal expansion drive. These types of actuators come in a variety of designs and would be well understood by those skilled in the art.

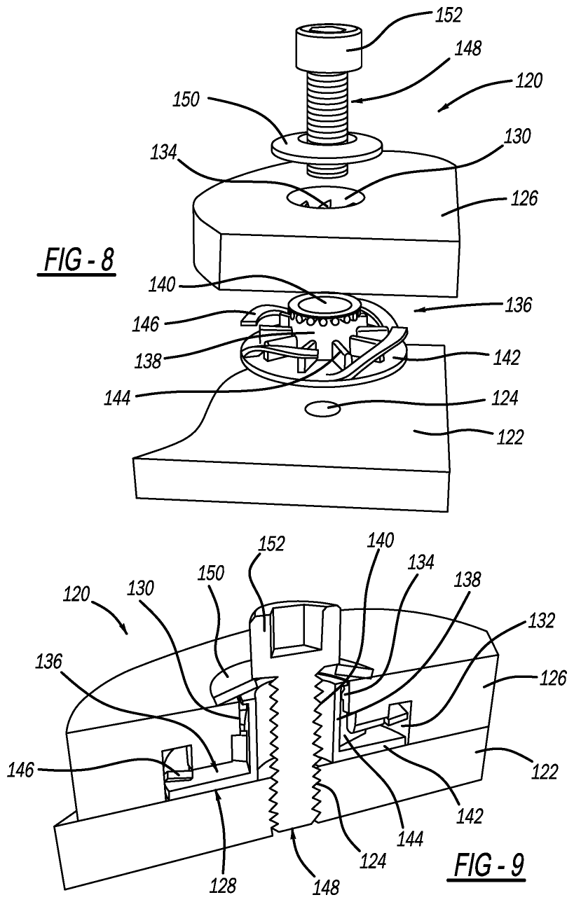

FIG. 8 is an exploded isometric view and FIG. 9 is a cross-sectional view of a rotary actuation device 120 that offers another actuator type that can be employed to provide compression pressure to a pressure dependent thermal conductance element (not shown) positioned between a heat source (not shown) and a heat sink (not shown). As will be discussed, the actuation device 120 is designed so that when it is engaged, the element is compressed and decompressed between full heat transfer compression and no heat transfer compression, so that it operates like a switch. The device 120 includes a lower plate 122 having a threaded bore 124 and an upper plate 126 including a cut-out section 128 defining a bore 130, an annular slot 132 and a series of teeth 134 configured in a circle within the slot 132 and the bore 130 and having gaps therebetween. A rotary member 136 is positioned in the cut-out section 128 so that a cylindrical portion 138 having a bore 140 is positioned within the bore 130 and a plate portion 142 rests on a top surface of the lower plate 122. The member 136 includes a series of spaced apart tabs 144 configured in a circle that are positioned in the gaps between the teeth 134 and a four spring ramps 146 extending around an outer periphery of the plate portion 142 and positioned within the slot 132. A bolt 148 extends through the bore 140 and is threaded into the threaded bore 124. A Bellville washer 150 is positioned between a head 152 of the bolt 148 and a top surface of the upper plate 126 and operates to hold the plates 122 and 126 together under compression. By pushing down on the bolt 148 against the bias of the washer 150, the plates 122 and 126 separate, which causes the teeth 134 to disengage from between the tabs 144 and the member 136 to rotate one space under spring pressure from the ramps 146.

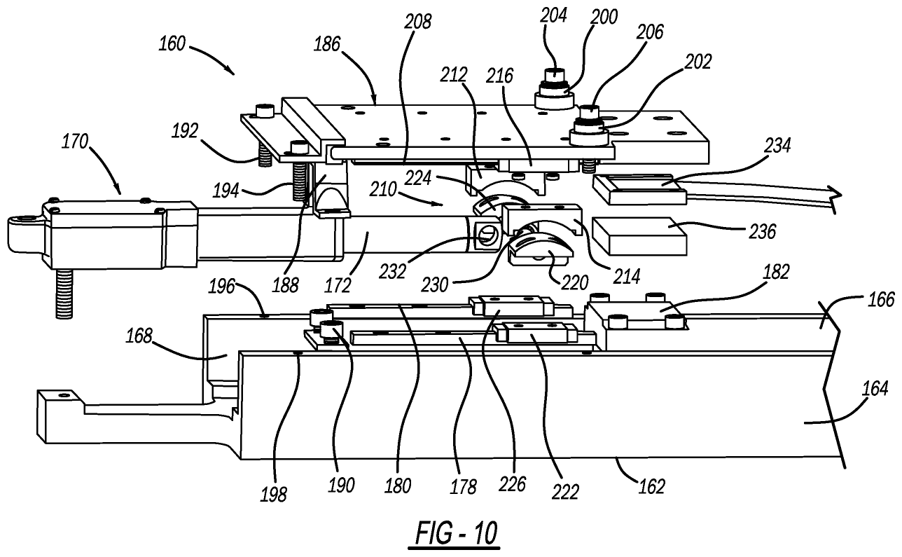

FIG. 10 is an exploded, cut-away, isometric view of a thermal management device 160 illustrating a practical application. The device 160 includes a base 162 having side walls 164 and 166 defining a channel 168 therebetween in which is mounted a linear actuator 170 including a piston 172. A slide rail 178 is bolted to a top of the side wall 164, a slide rail 180 is bolted to a top of the side wall 166 and a heat sink terminal 182 is bolted to the tops of the side walls 164 and 166 and extends across the channel 168. A hinged and spring-loaded compression plate 186 is mounted to the top surface of the side walls 164 and 166 at one end by risers 188 using bolts 190 and pins 192 and 194 inserted into pin holes 196 and 198, respectively. A pair of Belleville washers or springs 200 and 202 are bolted to a top surface of the plate 186 by bolts 204 and 206, respectively, and slide rails 208 are bolted to a bottom surface of the plate 186. A dynamic assembly 210 is positioned between the plate 186 and the base 162, and includes elliptical pieces 212 and 214 bolted to slides 216 that slide on the slide rails 208, an elliptical piece 220 bolted to a slide 222 that slides on the slide rail 178 and that engages the elliptical piece 214 and an elliptical piece 224 bolted to a slide 226 that slides on the slide rail 180 and that engages the elliptical piece 212. A pin 230 is secured to and extends between the elliptical pieces 220 and 224 and through an opening 232 in the piston 172. A heat source terminal 234 is secured to the bottom surface of the plate 186 opposite to the secured end of the plate 186 and relative to the heat sink terminal 182, and a pressure dependent thermal conductance element 236 is positioned between the terminals 182 and 234.

When the piston 172 is extended by the actuator 170, the dynamic assembly 230 slides forwards on the rails 178, 180 and 208, which causes the Belleville washers 200 and 202 to compress, which causes the plate 186 to push down on the heat source terminal 182 and increase the pressure on the thermal conductance element 236 between the heat source terminal 234 and the heat sink terminal 182, and thus increase the heat transfer therebetween. When the piston 172 is retracted by the actuator 170, the dynamic assembly 230 slides backwards on the rails 178, 180 and 208, which causes the Belleville washers 200 and 202 to decompress, which causes the plate 186 to lift up on the heat source terminal 234 and decrease the pressure on the thermal conductance element 236 between the heat source terminal 234 and the heat sink terminal 182, and thus reduce the heat transfer therebetween.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A thermal management system for transferring heat to and from a heat source, said system comprising:
a thermal conductor thermally coupled to the heat source;
at least one pressure dependent thermal conductance element thermally coupled to the conductor;
at least one heat sink thermally coupled to or thermally separable from the at least one thermal conductance element; and
at least one actuator configured relative to the thermal conductor, the at least one thermal conductance element and the at least one heat sink so as to control compression on the at least one thermal conductance element between the thermal conductor and the at least one heat sink so as to control the transfer of heat therebetween.

2. The system according to claim 1 wherein the at least one actuator creates a gap between the at least one thermal conductance element and the at least one heat sink to prevent heat transfer between the thermal conductor and the at least one heat sink.

3. The system according to claim 1 wherein the at least one actuator is selected from the group consisting of electric actuators, pneumatic actuators and expansion actuators.

4. The system according to claim 1 wherein the at least one actuator is a rotary actuator that selectively compresses or does not compress the at least one thermal conductance element.

5. The system according to claim 1 wherein the at least one thermal conductance element includes a compliant thermal interface material (TIM).

6. The system according to claim 5 wherein the TIM is selected from the group consisting of a nanowire array, a carbon nanotube forest and polymeric gaskets.

7. The system according to claim 1 wherein the thermal conductor is selected from the group consisting of a heat strap, a heat pipe and a heat spreader.

8. The system according to claim 1 wherein the at least one thermal conductance element is one thermal conductance element, the at least one heat sink is a plurality of heat sinks and the at least one actuator is a plurality of actuators, wherein the actuators selectively couple one of the heat sinks to the thermal conductance element.

9. The system according to claim 1 wherein the at least one thermal conductance element is one thermal conductance element and the at least one heat sink is a plurality of heat sinks.

10. The system according to claim 1 wherein the at least one thermal conductance element is a plurality of thermal conductance elements and the at least one heat sink is one heat sink.

11. The system according to claim 1 further comprising a sensor for measuring the heat transfer through the at least one thermal conductance element, said actuator controlling the compression on the at least one thermal conductance element based on the measured heat transfer.

12. A thermal management system comprising:
a heat source;
a compliant thermal interface material (TIM) element thermally coupled to the heat source;
a heat sink thermally coupled to the TIM element; and
an actuator configured to control compression on the TIM element so as to control the transfer of heat from the heat source to the heat sink.

13. The system according to claim 12 wherein the actuator creates a gap between the TIM element and the heat sink to prevent heat transfer between the heat source and the heat sink.

14. The system according to claim 12 wherein the actuator is selected from the group consisting of electric actuators, pneumatic actuators and expansion actuators.

15. The system according to claim 12 wherein the actuator is a rotary actuator that selectively compresses or does not compress the TIM element.

16. The system according to claim 12 wherein the TIM element is selected from the group consisting of a nanowire array, a carbon nanotube forest and polymeric gaskets.

17. The system according to claim 12 further comprising a sensor for measuring the heat transfer through the TIM element, said actuator controlling the compression on the TIM element based on the measured heat transfer.

18. A thermal management system for transferring heat from a heat source, said system comprising:
a thermal conductor thermally coupled to the heat source;
a pressure dependent thermal conductance element thermally coupled to the conductor;
a plurality of heat sinks thermally coupled to or thermally separable from the thermal conductance element; and
a plurality of actuators configured relative to the thermal conductor, the thermal conductance element and the plurality of heat sinks, wherein the actuators are selectively controlled to control compression on the thermal conductance element between the thermal conductor and a select one of the heat sinks so as to control the transfer of heat therebetween.

19. The system according to claim 18 wherein the thermal conductance element includes a compliant thermal interface material (TIM).

20. The system according to claim 18 further comprising a sensor for measuring the heat transfer through the thermal conductance element, said actuators controlling the compression on the thermal conductance element based on the measured heat transfer.
